(19) United States
(12) Patent Application Publication
(10) Pub. No.: US 2025/0393290 A1
(43) Pub. Date: Dec. 25, 2025

(54) FERROELECTRIC FIELD EFFECT TRANSISTORS (FEFETS) WITH RELAXOR FERROELECTRIC MATERIALS

(71) Applicant: Intel Corporation, Santa Clara, CA (US)

(72) Inventors: Arnab Sen Gupta, Hillsboro, OR (US); Pratyush P. Buragohain, Hillsboro, OR (US); Karam Cho, Hillsboro, OR (US); Raseong Kim, Portland, OR (US); Kevin P. O'Brien, Portland, OR (US); John J. Plombon, Portland, OR (US); Rachel A. Steinhardt, Beaverton, OR (US); I-Cheng Tung, Hillsboro, OR (US); Ian Alexander Young, Olympia, WA (US); Scott B. Clendenning, Portland, OR (US); Matthew V. Metz, Portland, OR (US)

(73) Assignee: Intel Corporation, Santa Clara, CA (US)

(21) Appl. No.: 18/750,215

(22) Filed: Jun. 21, 2024

(51) Int. Cl. H01L 29/51; H01L 29/78

(52) U.S. Cl. CPC H10D 64/689; H10D 30/701

(57) ABSTRACT

In embodiments of the present disclosure, a field effect transistor includes a ferroelectric gate dielectric layer with a relaxor ferroelectric material. The relaxor ferroelectric may include, for example, (BaₓCa₍₁₋ₓ₎)(Ti_{y}Zr_{(1-y)})O₃, a solid solution of BiFeO₃ and BTO, BaZrₓTi₍₁₋ₓ₎O₃, or BaNbₓTi_{(1-5x/4)}O₃.

### BACKGROUND

Transistors are ubiquitous devices present in virtually all electronic devices. As the density of transistors continues to increase, the power dissipated by the transistors needs to be addressed. The power dissipation of a transistor can be reduced in several ways, such as reducing leakage current and reducing the threshold voltage of the transistor.

A typical transistor can maintain its state when a voltage is maintained at a gate electrode. However, a ferroelectric field-effect transistor (FEFET) can maintain its state based on a state of a ferroelectric layer in the transistor. FEFETs typically have a relatively high threshold voltage and a corresponding relatively high leakage current.

### BRIEF DESCRIPTION OF THE DRAWINGS

FIGS. 1A-1D are perspective views of example planar, FinFET, gate-all-around (GAA), and stacked gate-all-around transistors.

FIGS. 2A-2B illustrate an example planar transistor with a gate dielectric that includes a relaxor ferroelectric material in accordance with embodiments herein.

FIG. 3 illustrates another example planar transistor with a gate dielectric that includes a relaxor ferroelectric material in accordance with embodiments herein.

FIG. 4 illustrates an example FinFET transistor with a gate dielectric that includes a relaxor ferroelectric material in accordance with embodiments herein.

FIG. 5 illustrates an example GAA transistor with a gate dielectric that includes a relaxor ferroelectric material in accordance with embodiments herein.

FIG. 6 is a top view of a wafer and dies that may be included in embodiments disclosed herein.

FIG. 7 is a cross-sectional side view of an integrated circuit device that may be included in embodiments herein.

FIG. 8 is a cross-sectional side view of an integrated circuit device assembly that may include embodiments disclosed herein.

FIG. 9 is a block diagram of an example electrical device that may include embodiments disclosed herein.

### DETAILED DESCRIPTION

Embodiments herein relate to ferroelectric field-effect transistors that include relaxor ferroelectric material layers. Ferroelectric field-effect transistors (FeFETs) can use the spontaneous polarization in a ferroelectric material to apply an electric displacement to raise or lower a gate voltage above or below a threshold voltage. The orientation of the spontaneous polarization in the ferroelectric material can be changed by the application of an electric field to a gate of the transistor, allowing the transistor to be used as a memory cell. For instance, if an applied gate voltage causes an electric field above a coercive voltage for the ferroelectric material, the direction of the spontaneous polarization of the ferroelectric material can switch.

Typically, FeFETs utilize BaTiO₃ (sometimes referred to as “BTO”) as the ferroelectric gate dielectric material. BTO grown on a silicon substrate may have a coercive voltage between approximately 0.4V-1V. However, as integrated circuit devices continue to scale down and utilize lower operating voltages, it is desirable to have lower coercive voltages in FeFETs.

Accordingly, embodiments herein may implement FeFETs with relaxor ferroelectric materials in the gate dielectric. A relaxor ferroelectric material may refer to a particular type of ferroelectric material that exhibit high electrostriction. Typically, ferroelectric materials may illustrate sharp transition from a paraelectric to a ferroelectric phase. Relaxor ferroelectrics, however, may exhibit a more gradual phase change than traditional ferroelectric materials (sometimes referred to as a diffused transition). This is because small nanodomains within the relaxor ferroelectric grow during the transition from a paraelectric to a ferroelectric phase.

Relaxor ferroelectric materials may have lower coercive fields than undoped lead zirconium titanate (PZT), BTO films, or other typical ferroelectrics, due to the formation of compositional fluctuations, which leads to the formation of short-range order polar nano-regions (PNRs). Accordingly, relaxor ferroelectric materials may exhibit lower coercive voltages than PZT, BTO, or other commonly-used ferroelectrics, e.g., with coercive voltages of less than 0.5V. In addition, One example relaxor ferroelectric material is (BaₓCa₍₁₋ₓ₎)(Ti_{y}Zr_{(1-y)})O₃, where, for example, x=0.85 and y=0.90 (which may sometimes be referred to as “15/10BCTZ”). Another example relaxor ferroelectric material is a solid solution of BiFeO₃ and BTO (sometimes referred to as “BFO/BTO”). Other example relaxor ferroelectric materials include BaZrₓTi₍₁₋ₓ₎O₃ and BaNbₓTi_{(1-5x/4)}O₃.

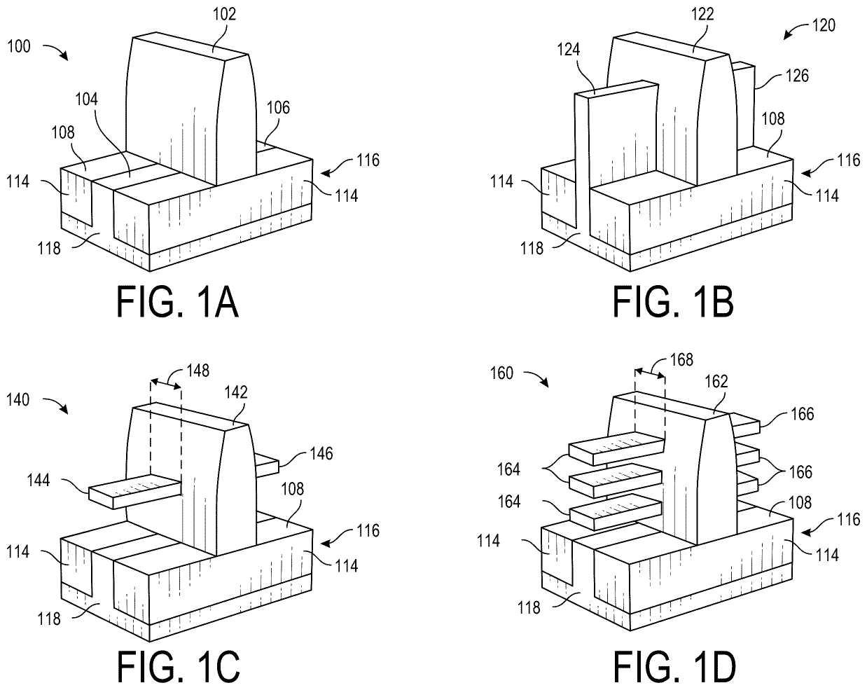

FIGS. 1A-1D are simplified perspective views of example planar, FinFET, gate-all-around, and stacked gate-all-around transistors. Any of the example transistors shown (including their variants) can include a relaxor type ferroelectric gate dielectric layer in accordance with embodiments of the present disclosure. The transistors illustrated in FIGS. 1A-1D are formed on a substrate 116 having a surface 108. Isolation regions 114 separate the source and drain regions of the transistors from other transistors and from a bulk region 118 of the substrate 116.

FIG. 1A is a perspective view of an example planar transistor 100 comprising a gate 102 that controls current flow between a source region 104 and a drain region 106. The transistor 100 is planar in that the source region 104 and the drain region 106 are planar with respect to the substrate surface 108.

FIG. 1B is a perspective view of an example FinFET transistor 120 comprising a gate 122 that controls current flow between a source region 124 and a drain region 126. The transistor 120 is non-planar in that the source region 124 and the drain region 126 comprise “fins” that extend upwards from the substrate surface. As the gate 122 encompasses three sides of the semiconductor fin that extends from the source region 124 to the drain region 126, the transistor 120 can be considered a tri-gate transistor. FIG. 1B illustrates one S/D fin extending through the gate 122, but multiple S/D fins can extend through the gate of a FinFET transistor.

FIG. 1C is a perspective view of a gate-all-around (GAA) transistor 140 comprising a gate 142 that controls current flow between a source region 144 and a drain region 146. The transistor 140 is non-planar in that the source region 144 and the drain region 146 are elevated from the substrate surface.

FIG. 1D is a perspective view of a GAA transistor 160 comprising a gate 162 that controls current flow between multiple elevated source regions 164 and multiple elevated drain regions 166. The transistor 160 is a stacked GAA transistor as the gate controls the flow of current between multiple elevated S/D regions stacked on top of each other. The transistors 140 and 160 are considered gate-all-around transistors as the gates encompass all sides of the semiconductor portions that extends from the source regions to the drain regions, forming the transistor channels. The transistors 140 and 160 can alternatively be referred to as nanowire, nanosheet, or nanoribbon transistors depending on the width (e.g., widths 148 and 168 of transistors 140 and 160, respectively) or shape of the semiconductor portions extending through the gate. Although the transistor 160 includes three semiconductor portions (nanowires, nanosheets, or nanoribbons) extending through the gate 162, other embodiments may include two or more than three semiconductor portions.

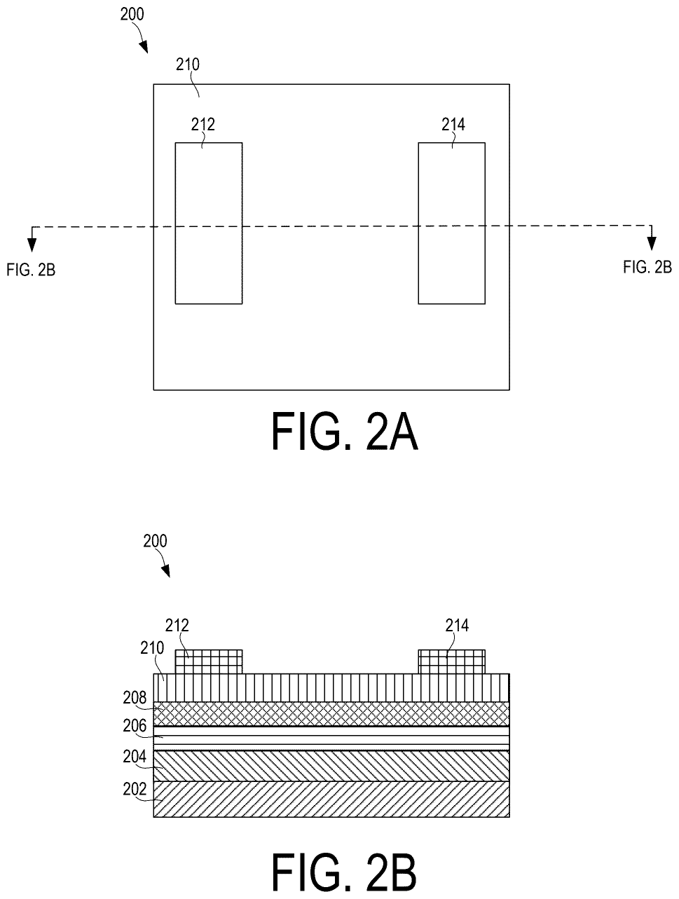

FIGS. 2A-2B illustrate an example planar transistor 200 with a gate dielectric that includes a relaxor ferroelectric material in accordance with embodiments herein. This transistor configuration may be referred to as an ferroelectric field effect transistor (FeFET). FIG. 2A shows a top-down view of the transistor 200, and FIG. 2B shows a cross-sectional view of the transistor 200. The example transistor 200 includes a substrate 202, a buffer layer 204, a gate electrode 206, a ferroelectric layer 208, a channel 210, a source electrode 212, and a drain electrode 214.

In use, a voltage can be applied to the gate electrode 206, which causes an electric field to be applied to the ferroelectric layer 208 and to the channel 210. If the applied voltage causes an electric field above a coercive field, the direction of the spontaneous polarization of the ferroelectric material can switch. The electric displacement of the ferroelectric material is the spontaneous polarization of the ferroelectric when no electric field is applied by the ferroelectric layer 208. Under the applied field from the voltage of the gate electrode 206, the electric displacement of the ferroelectric material increases. As a result, the electric displacement applied to the channel 210 is affected by the polarization state of the ferroelectric material of the layer 208, and, therefore, the current through the channel 210 is affected by the polarization state of the ferroelectric material of the layer 208. The transistor 200 (and other ferroelectric transistors described herein) can accordingly be used to facilitate low-threshold switching, single transistor memory, and compute-in-memory.

The threshold voltage of the transistor 200 depends on the ferroelectric layer 208 material as well as the channel 210 thickness and doping concentration. In embodiments herein, the ferroelectric layer 208 may include a relaxor ferroelectric, such as the examples described above. The threshold voltage of the transistor 200 may be less than 0.5V, e.g., approximately 250 mV. When a voltage at or above the threshold voltage is applied to the gate electrode 206, the polarization of the ferroelectric material of the ferroelectric layer 208 increases the electric displacement applied to the channel 210.

In some embodiments, the polarization of the ferroelectric layer 208 switches all at once in a few picoseconds. In other embodiments, the ferroelectric layer 208 may have multiple domains that may switch at different applied electric fields (and, therefore, at different times). In such embodiments, the ferroelectric layer 208 may have multiple stable states that can be set by applying a particular voltage to the gate electrode 206. Such a transistor 200 can act as a multi-level memory or like an analog memory.

In some embodiments, the substrate 202 may be silicon, with a buffer layer 204 also present. The buffer layer 204 may include materials that allow for better adhesion with other layers than a silicon substrate 202. In some embodiments, the substrate 202 may be a different material, such as germanium, indium antimonide, lead telluride, indium arsenide, indium phosphide, gallium arsenide, indium gallium arsenide, gallium antimonide, or other combinations of group III-V, group II-VI, or group IV materials. In some embodiments, the substrate 202 is gallium nitride (GaN), aluminum nitride (AlN) or aluminum oxide (Al₂O₃), and the various layers, such as the gate electrode 206, ferroelectric layer 208, and channel 210, can be formed directly on the substrate 202 without a buffer layer 204. In some embodiments, the structure of the transistor 200 (or the transistors 400, 500 discussed below) may be formed on a separate substrate, such as a gallium nitride substrate, and then transferred to the substrate 202 using wafer bonding. Either chiplets or components for an entire wafer may be transferred in such a manner.

The gate electrode 206 may be any suitable conductive material, such as titanium nitride or platinum. The channel 210 may be, e.g., gallium nitride (GaN) or molybdenum disulfide (MoS₂). The source electrode 212 and/or drain electrode 214 may be any suitable material, such as titanium nitride, gold, or other conductive material.

The channel 210 may include a source region under the source electrode 212, and a drain region under the drain electrode 214 (not explicitly shown in FIGS. 2A-2B). The source region and drain region may be doped. For example, for an n-doped channel 210, the source region and drain region may be n-doped, and for a p-doped channel 210, the source region and drain region may be p-doped. In the example shown, the transistor 200 is symmetric, and there is no functional distinction between the source region and the drain region. The source/drain regions may be formed using either an implantation/diffusion process or an etching/deposition process. In the former process, dopants such as lanthanum, boron, aluminum, antimony, phosphorous, or arsenic may be ion-implanted into the channel material to form the source/drain regions. An annealing process that activates the dopants and causes them to diffuse further into the channel 210 may follow the ion implantation process. In the latter process, the channel 210 may first be etched to form recesses at the locations of the source regions. An epitaxial deposition process may then be carried out to fill the recesses with material that is used to fabricate the source/drain regions.

In the example shown, some or all of the various layers and components of the transistor 200 are in the form of a thin-films deposited on the substrate 202 or the buffer layer 204. The thin-film layers may be deposited in any suitable manner. For example, the ferroelectric layer 208 may be deposited as a thin film using, e.g., atomic layer deposition, molecular beam epitaxy, pulsed laser deposition, physical vapor deposition, sputter deposition, etc. The thickness of the various layers (e.g., the gate electrode 206, the ferroelectric layer 208, the channel 210, etc.) may be any suitable value, such as 0.5-200 nanometers. In some embodiments, the ferroelectric layer 208 may have a thickness of, e.g., 1-50 nanometers, and the channel 210 may have a thickness of, e.g., 2-100 nanometers.

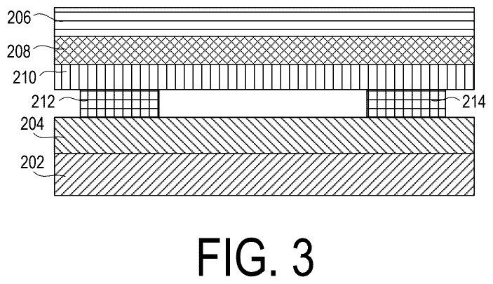

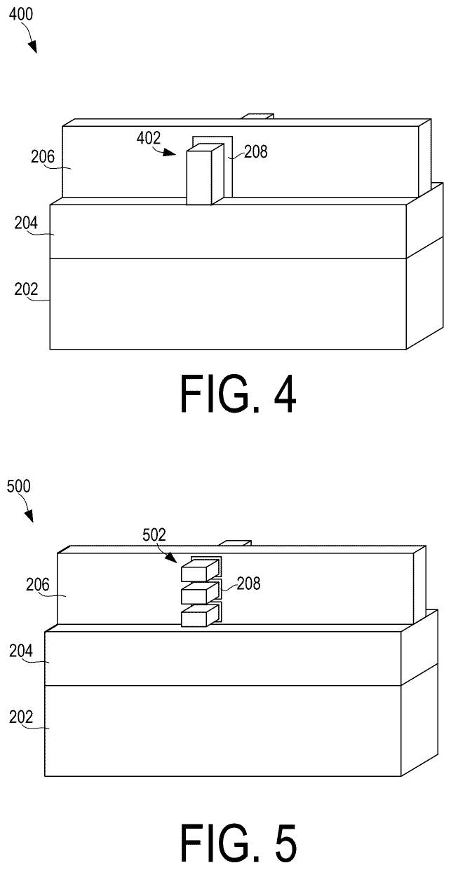

In the example shown, the transistor 200 has a bottom gate and top contact configuration. In other embodiments, the transistor 200 may be filled, with a bottom contact configuration and a top gate, as shown in FIG. 3. Other configurations are possible as well. For example, FIG. 4 shows a fin field-effect transistor (FinFET), with fins 402 extending along the buffer layer 204, with the gate electrode 206 covering the fin 402, separated by the ferroelectric layer 208. Each end of the fin 402 may be doped to be source/drain regions, and a center area of the fin 402 by the gate electrode 206 and the ferroelectric layer 208 may be doped to be the channel. In another example, FIG. 5 shows a gate-all-around (GAA) configuration, with several nanoribbons or nanowires 502 acting as the source region and the drain region surrounded by the gate electrode 206 and the ferroelectric layer 208, in a similar manner as the fins 402 of FIG. 4.

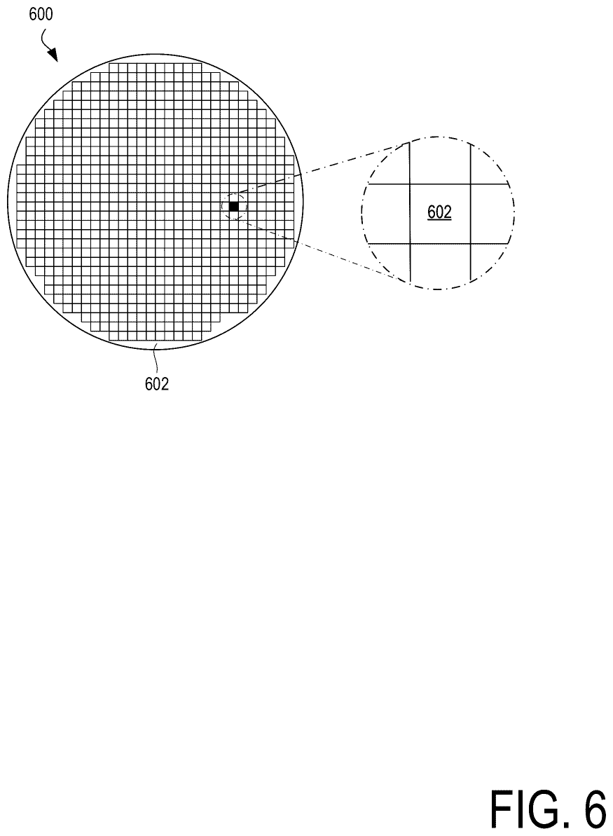

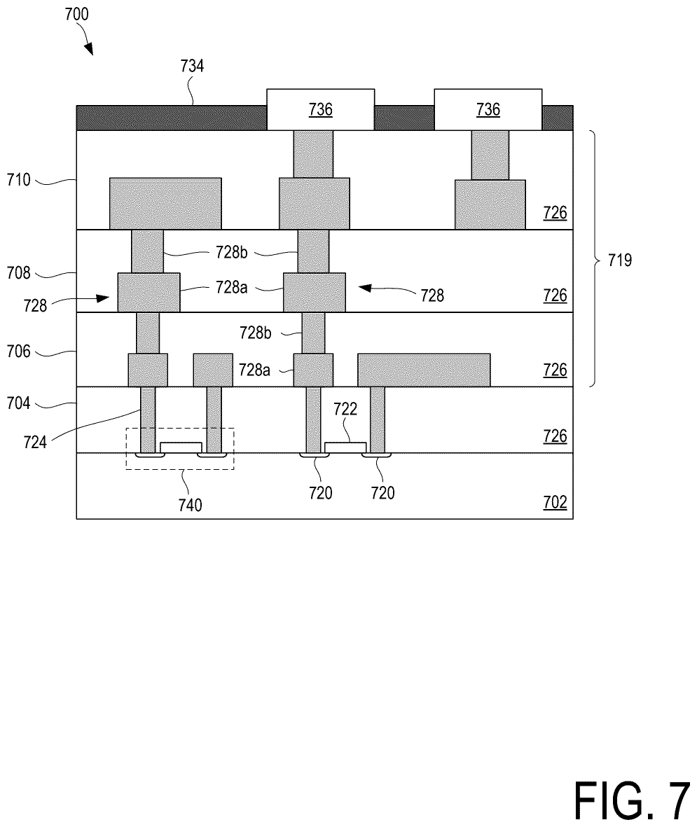

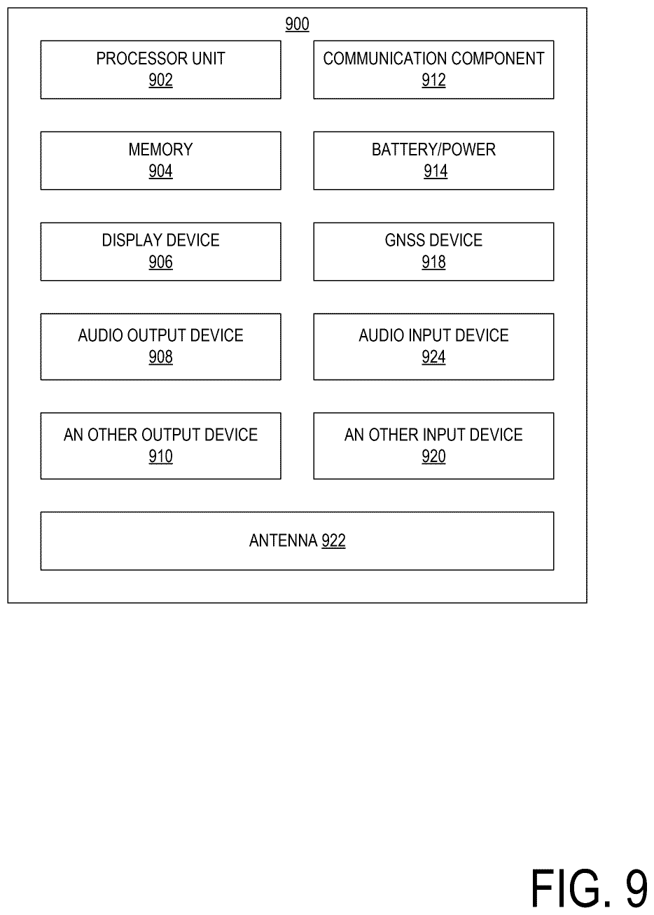

FIG. 6 is a top view of a wafer 600 and dies 602 that may incorporate any of the embodiments disclosed herein. The wafer 600 may be composed of semiconductor material and may include one or more dies 602 having integrated circuit structures formed on a surface of the wafer 600. The individual dies 602 may be a repeating unit of an integrated circuit product that includes any suitable integrated circuit. After the fabrication of the semiconductor product is complete, the wafer 600 may undergo a singulation process in which the dies 602 are separated from one another to provide discrete “chips” of the integrated circuit product. The die 602 may include one or more transistors (e.g., some of the transistors 740 of FIG. 7, discussed below), supporting circuitry to route electrical signals to the transistors, passive components (e.g., signal traces, resistors, capacitors, or inductors), and/or any other integrated circuit components. In some embodiments, the wafer 600 or the die 602 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 602. For example, a memory array formed by multiple memory devices may be formed on a same die 602 as a processor unit (e.g., the processor unit 902 of FIG. 9) or other logic that is configured to store information in the memory devices or execute instructions stored in the memory array.

FIG. 7 is a cross-sectional side view of an integrated circuit device 700 that may be included in embodiments herein. One or more of the integrated circuit devices 700 may be included in one or more dies 602 (FIG. 6). The integrated circuit device 700 may be formed on a die substrate 702 (e.g., the wafer 600 of FIG. 6) and may be included in a die (e.g., the die 602 of FIG. 6). The die substrate 702 may be a semiconductor substrate composed of semiconductor material systems including, for example, n-type or p-type materials systems (or a combination of both). The die substrate 702 may include, for example, a crystalline substrate formed using a bulk silicon or a silicon-on-insulator (SOI) substructure. In some embodiments, the die substrate 702 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 702. Although a few examples of materials from which the die substrate 702 may be formed are described here, any material that may serve as a foundation for an integrated circuit device 700 may be used. The die substrate 702 may be part of a singulated die (e.g., the dies 602 of FIG. 6) or a wafer (e.g., the wafer 600 of FIG. 6).

The integrated circuit device 700 may include one or more device layers 704 disposed on the die substrate 702. The device layer 704 may include features of one or more transistors 740 (e.g., FeFETs as described herein) formed on the die substrate 702. The transistors 740 may include, for example, one or more source and/or drain (S/D) regions 720, a gate 722 to control current flow between the S/D regions 720, and one or more S/D contacts 724 to route electrical signals to/from the S/D regions 720. The transistors 740 may include additional features not depicted for the sake of clarity, such as device isolation regions, gate contacts, and the like. The transistors 740 are not limited to the type and configuration depicted in FIG. 7 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

A transistor 740 may include a gate 722 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 740 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 740 along the source-channel-drain direction, the gate electrode may consist of a U-shaped structure that includes a bottom portion substantially parallel to the surface of the die substrate 702 and two sidewall portions that are substantially perpendicular to the top surface of the die substrate 702. In other embodiments, at least one of the metal layers that form the gate electrode may simply be a planar layer that is substantially parallel to the top surface of the die substrate 702 and does not include sidewall portions substantially perpendicular to the top surface of the die substrate 702. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 720 may be formed within the die substrate 702 adjacent to the gate 722 of individual transistors 740. The S/D regions 720 may be formed using an implantation/diffusion process or an etching/deposition process, for example. In the former process, dopants such as boron, aluminum, antimony, phosphorous, or arsenic may be ion-implanted into the die substrate 702 to form the S/D regions 720. An annealing process that activates the dopants and causes them to diffuse farther into the die substrate 702 may follow the ion-implantation process. In the latter process, the die substrate 702 may first be etched to form recesses at the locations of the S/D regions 720. An epitaxial deposition process may then be carried out to fill the recesses with material that is used to fabricate the S/D regions 720. In some implementations, the S/D regions 720 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 720 may be formed using one or more alternate semiconductor materials such as germanium or a group III-V material or alloy. In further embodiments, one or more layers of metal and/or metal alloys may be used to form the S/D regions 720.

Electrical signals, such as power and/or input/output (I/O) signals, may be routed to and/or from the devices (e.g., transistors 740) of the device layer 704 through one or more interconnect layers disposed on the device layer 704 (illustrated in FIG. 7 as interconnect layers 706-710). For example, electrically conductive features of the device layer 704 (e.g., the gate 722 and the S/D contacts 724) may be electrically coupled with the interconnect structures 728 of the interconnect layers 706-710. The one or more interconnect layers 706-710 may form a metallization stack (also referred to as an “ILD stack”) 719 of the integrated circuit device 700.

The interconnect structures 728 may be arranged within the interconnect layers 706-710 to route electrical signals according to a wide variety of designs; in particular, the arrangement is not limited to the particular configuration of interconnect structures 728 depicted in FIG. 7. Although a particular number of interconnect layers 706-710 is depicted in FIG. 7, embodiments of the present disclosure include integrated circuit devices having more or fewer interconnect layers than depicted.

In some embodiments, the interconnect structures 728 may include lines 728a and/or vias 728b filled with an electrically conductive material such as a metal. The lines 728a may be arranged to route electrical signals in a direction of a plane that is substantially parallel with a surface of the die substrate 702 upon which the device layer 704 is formed. For example, the lines 728a may route electrical signals in a direction in and out of the page and/or in a direction across the page from the perspective of FIG. 7. The vias 728b may be arranged to route electrical signals in a direction of a plane that is substantially perpendicular to the surface of the die substrate 702 upon which the device layer 704 is formed. In some embodiments, the vias 728b may electrically couple lines 728a of different interconnect layers 706-710 together.

The interconnect layers 706-710 may include a dielectric material 726 disposed between the interconnect structures 728, as shown in FIG. 7. In some embodiments, dielectric material 726 disposed between the interconnect structures 728 in different ones of the interconnect layers 706-710 may have different compositions; in other embodiments, the composition of the dielectric material 726 between different interconnect layers 706-710 may be the same. The device layer 704 may include a dielectric material 726 disposed between the transistors 740 and a bottom layer of the metallization stack as well. The dielectric material 726 included in the device layer 704 may have a different composition than the dielectric material 726 included in the interconnect layers 706-710; in other embodiments, the composition of the dielectric material 726 in the device layer 704 may be the same as a dielectric material 726 included in any one of the interconnect layers 706-710.

A first interconnect layer 706 (referred to as Metal 1 or “M1”) may be formed directly on the device layer 704. In some embodiments, the first interconnect layer 706 may include lines 728a and/or vias 728b, as shown. The lines 728a of the first interconnect layer 706 may be coupled with contacts (e.g., the S/D contacts 724) of the device layer 704. The vias 728b of the first interconnect layer 706 may be coupled with the lines 728a of a second interconnect layer 708.

The second interconnect layer 708 (referred to as Metal 2 or “M2”) may be formed directly on the first interconnect layer 706. In some embodiments, the second interconnect layer 708 may include via 728b to couple the lines 728a of the second interconnect layer 708 with the lines 728a of a third interconnect layer 710. Although the lines 728a and the vias 728b are structurally delineated with a line within individual interconnect layers for the sake of clarity, the lines 728a and the vias 728b may be structurally and/or materially contiguous (e.g., simultaneously filled during a dual-damascene process) in some embodiments.

The third interconnect layer 710 (referred to as Metal 3 or “M3”) (and additional interconnect layers, as desired) may be formed in succession on the second interconnect layer 708 according to similar techniques and configurations described in connection with the second interconnect layer 708 or the first interconnect layer 706. In some embodiments, the interconnect layers that are “higher up” in the metallization stack 719 in the integrated circuit device 700 (i.e., farther away from the device layer 704) may be thicker that the interconnect layers that are lower in the metallization stack 719, with lines 728a and vias 728b in the higher interconnect layers being thicker than those in the lower interconnect layers.

The integrated circuit device 700 may include a solder resist material 734 (e.g., polyimide or similar material) and one or more conductive contacts 736 formed on the interconnect layers 706-710. In FIG. 7, the conductive contacts 736 are illustrated as taking the form of bond pads. The conductive contacts 736 may be electrically coupled with the interconnect structures 728 and configured to route the electrical signals of the transistor(s) 740 to external devices. For example, solder bonds may be formed on the one or more conductive contacts 736 to mechanically and/or electrically couple an integrated circuit die including the integrated circuit device 700 with another component (e.g., a printed circuit board). The integrated circuit device 700 may include additional or alternate structures to route the electrical signals from the interconnect layers 706-710; for example, the conductive contacts 736 may include other analogous features (e.g., posts) that route the electrical signals to external components.

In some embodiments in which the integrated circuit device 700 is a double-sided die, the integrated circuit device 700 may include another metallization stack (not shown) on the opposite side of the device layer(s) 704. This metallization stack may include multiple interconnect layers as discussed above with reference to the interconnect layers 706-710, to provide conductive pathways (e.g., including conductive lines and vias) between the device layer(s) 704 and additional conductive contacts (not shown) on the opposite side of the integrated circuit device 700 from the conductive contacts 736.

In other embodiments in which the integrated circuit device 700 is a double-sided die, the integrated circuit device 700 may include one or more through silicon vias (TSVs) through the die substrate 702; these TSVs may make contact with the device layer(s) 704, and may provide conductive pathways between the device layer(s) 704 and additional conductive contacts (not shown) on the opposite side of the integrated circuit device 700 from the conductive contacts 736. In some embodiments, TSVs extending through the substrate can be used for routing power and ground signals from conductive contacts on the opposite side of the integrated circuit device 700 from the conductive contacts 736 to the transistors 740 and any other components integrated into the die, and the metallization stack 719 can be used to route I/O signals from the conductive contacts 736 to transistors 740 and any other components integrated into the die.

Multiple integrated circuit devices 700 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

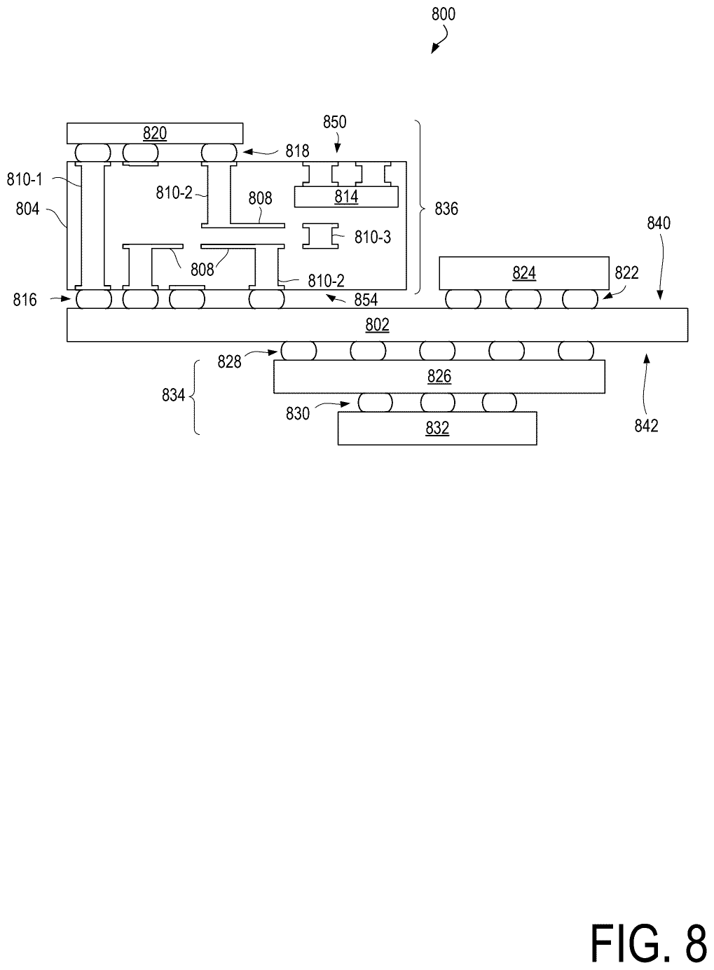

FIG. 8 is a cross-sectional side view of an integrated circuit device assembly 800 that may include any of the embodiments disclosed herein. The integrated circuit device assembly 800 includes a number of components disposed on a circuit board 802 (which may be a motherboard, system board, mainboard, etc.). The integrated circuit device assembly 800 includes components disposed on a first face 840 of the circuit board 802 and an opposing second face 842 of the circuit board 802; generally, components may be disposed on one or both faces 840 and 842.

In some embodiments, the circuit board 802 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 802. In other embodiments, the circuit board 802 may be a non-PCB substrate. The integrated circuit device assembly 800 illustrated in FIG. 8 includes a package-on-interposer structure 836 coupled to the first face 840 of the circuit board 802 by coupling components 816. The coupling components 816 may electrically and mechanically couple the package-on-interposer structure 836 to the circuit board 802, and may include solder balls (as shown in FIG. 8), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 836 may include an integrated circuit component 820 coupled to an interposer 804 by coupling components 818. The coupling components 818 may take any suitable form for the application, such as the forms discussed above with reference to the coupling components 816. Although a single integrated circuit component 820 is shown in FIG. 8, multiple integrated circuit components may be coupled to the interposer 804; indeed, additional interposers may be coupled to the interposer 804. The interposer 804 may provide an intervening substrate used to bridge the circuit board 802 and the integrated circuit component 820.

The integrated circuit component 820 may be a packaged or unpacked integrated circuit product that includes one or more integrated circuit dies (e.g., the die 602 of FIG. 6, the integrated circuit device 700 of FIG. 7) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 820, a single monolithic integrated circuit die comprises solder bumps attached to contacts on the die. The solder bumps allow the die to be directly attached to the interposer 804. The integrated circuit component 820 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 820 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 820 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 820 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 804 may spread connections to a wider pitch or reroute a connection to a different connection. For example, the interposer 804 may couple the integrated circuit component 820 to a set of ball grid array (BGA) conductive contacts of the coupling components 816 for coupling to the circuit board 802. In the embodiment illustrated in FIG. 8, the integrated circuit component 820 and the circuit board 802 are attached to opposing sides of the interposer 804; in other embodiments, the integrated circuit component 820 and the circuit board 802 may be attached to a same side of the interposer 804. In some embodiments, three or more components may be interconnected by way of the interposer 804.

In some embodiments, the interposer 804 may be formed as a PCB, including multiple metal layers separated from one another by layers of dielectric material and interconnected by electrically conductive vias. In some embodiments, the interposer 804 may be formed of an epoxy resin, a fiberglass-reinforced epoxy resin, an epoxy resin with inorganic fillers, a ceramic material, or a polymer material such as polyimide. In some embodiments, the interposer 804 may be formed of alternate rigid or flexible materials that may include the same materials described above for use in a semiconductor substrate, such as silicon, germanium, and other group III-V and group IV materials. The interposer 804 may include metal interconnects 808 and vias 810, including but not limited to through hole vias 810-1 (that extend from a first face 850 of the interposer 804 to a second face 854 of the interposer 804), blind vias 810-2 (that extend from the first or second faces 850 or 854 of the interposer 804 to an internal metal layer), and buried vias 810-3 (that connect internal metal layers).

In some embodiments, the interposer 804 can comprise a silicon interposer. Through silicon vias (TSV) extending through the silicon interposer can connect connections on a first face of a silicon interposer to an opposing second face of the silicon interposer. In some embodiments, an interposer 804 comprising a silicon interposer can further comprise one or more routing layers to route connections on a first face of the interposer 804 to an opposing second face of the interposer 804.

The interposer 804 may further include embedded devices 814, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 804. The package-on-interposer structure 836 may take the form of any of the package-on-interposer structures known in the art. In embodiments where the interposer is a non-printed circuit board

The integrated circuit device assembly 800 may include an integrated circuit component 824 coupled to the first face 840 of the circuit board 802 by coupling components 822. The coupling components 822 may take the form of any of the embodiments discussed above with reference to the coupling components 816, and the integrated circuit component 824 may take the form of any of the embodiments discussed above with reference to the integrated circuit component 820.

The integrated circuit device assembly 800 illustrated in FIG. 8 includes a package-on-package structure 834 coupled to the second face 842 of the circuit board 802 by coupling components 828. The package-on-package structure 834 may include an integrated circuit component 826 and an integrated circuit component 832 coupled together by coupling components 830 such that the integrated circuit component 826 is disposed between the circuit board 802 and the integrated circuit component 832. The coupling components 828 and 830 may take the form of any of the embodiments of the coupling components 816 discussed above, and the integrated circuit components 826 and 832 may take the form of any of the embodiments of the integrated circuit component 820 discussed above. The package-on-package structure 834 may be configured in accordance with any of the package-on-package structures known in the art.

FIG. 9 is a block diagram of an example electrical device 900 that may include one or more of the embodiments disclosed herein. For example, any suitable ones of the components of the electrical device 900 may include one or more of the integrated circuit device assemblies 800, integrated circuit components 820, integrated circuit devices 700, or integrated circuit dies 602 disclosed herein. A number of components are illustrated in FIG. 9 as included in the electrical device 900, but any one or more of these components may be omitted or duplicated, as suitable for the application. In some embodiments, some or all of the components included in the electrical device 900 may be attached to one or more motherboards mainboards, or system boards. In some embodiments, one or more of these components are fabricated onto a single system-on-a-chip (SoC) die.

Additionally, in various embodiments, the electrical device 900 may not include one or more of the components illustrated in FIG. 9, but the electrical device 900 may include interface circuitry for coupling to the one or more components. For example, the electrical device 900 may not include a display device 906, but may include display device interface circuitry (e.g., a connector and driver circuitry) to which a display device 906 may be coupled. In another set of examples, the electrical device 900 may not include an audio input device 924 or an audio output device 908, but may include audio input or output device interface circuitry (e.g., connectors and supporting circuitry) to which an audio input device 924 or audio output device 908 may be coupled.

The electrical device 900 may include one or more processor units 902 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 902 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 900 may include a memory 904, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 904 may include memory that is located on the same integrated circuit die as the processor unit 902. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 900 can comprise one or more processor units 902 that are heterogeneous or asymmetric to another processor unit 902 in the electrical device 900. There can be a variety of differences between the processing units 902 in a system in terms of a spectrum of metrics of merit including architectural, microarchitectural, thermal, power consumption characteristics, and the like. These differences can effectively manifest themselves as asymmetry and heterogeneity among the processor units 902 in the electrical device 900.

In some embodiments, the electrical device 900 may include a communication component 912 (e.g., one or more communication components). For example, the communication component 912 can manage wireless communications for the transfer of data to and from the electrical device 900. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 912 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 912 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 912 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 912 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 912 may operate in accordance with other wireless protocols in other embodiments. The electrical device 900 may include an antenna 922 to facilitate wireless communications and/or to receive other wireless communications (such as AM or FM radio transmissions).

In some embodiments, the communication component 912 may manage wired communications, such as electrical, optical, or any other suitable communication protocols (e.g., IEEE 802.3 Ethernet standards). As noted above, the communication component 912 may include multiple communication components. For instance, a first communication component 912 may be dedicated to shorter-range wireless communications such as Wi-Fi or Bluetooth, and a second communication component 912 may be dedicated to longer-range wireless communications such as global positioning system (GPS), EDGE, GPRS, CDMA, WiMAX, LTE, EV-DO, or others. In some embodiments, a first communication component 912 may be dedicated to wireless communications, and a second communication component 912 may be dedicated to wired communications.

The electrical device 900 may include battery/power supply circuitry 914. The battery/power supply circuitry 914 may include one or more energy storage devices (e.g., batteries or capacitors) and/or circuitry for coupling components of the electrical device 900 to an energy source separate from the electrical device 900 (e.g., AC line power).

The electrical device 900 may include a display device 906 (or corresponding interface circuitry, as discussed above). The display device 906 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 900 may include an audio output device 908 (or corresponding interface circuitry, as discussed above). The audio output device 908 may include any embedded or wired or wirelessly connected external device that generates an audible indicator, such speakers, headsets, or earbuds.

The electrical device 900 may include an audio input device 924 (or corresponding interface circuitry, as discussed above). The audio input device 924 may include any embedded or wired or wirelessly connected device that generates a signal representative of a sound, such as microphones, microphone arrays, or digital instruments (e.g., instruments having a musical instrument digital interface (MIDI) output). The electrical device 900 may include a Global Navigation Satellite System (GNSS) device 918 (or corresponding interface circuitry, as discussed above), such as a Global Positioning System (GPS) device. The GNSS device 918 may be in communication with a satellite-based system and may determine a geolocation of the electrical device 900 based on information received from one or more GNSS satellites, as known in the art.

The electrical device 900 may include another output device 910 (or corresponding interface circuitry, as discussed above). Examples of the other output device 910 may include an audio codec, a video codec, a printer, a wired or wireless transmitter for providing information to other devices, or an additional storage device.

The electrical device 900 may include another input device 920 (or corresponding interface circuitry, as discussed above). Examples of the other input device 920 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 900 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 900 may be any other electronic device that processes data. In some embodiments, the electrical device 900 may comprise multiple discrete physical components. Given the range of devices that the electrical device 900 can be manifested as in various embodiments, in some embodiments, the electrical device 900 can be referred to as a computing device or a computing system.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 is a transistor device comprising: a source region; a drain region; a channel region between the source region and the drain region; a gate electrode; and a dielectric between the gate electrode and the channel region, wherein the dielectric is ferroelectric and the dielectric comprises barium, titanium, oxygen, and one or more of calcium, zirconium, bismuth, iron, and niobium.

Example 2 includes the subject matter of Example 1, wherein the dielectric comprises barium, calcium, titanium, zirconium, and oxygen.

Example 3 includes the subject matter of Example 1, wherein the dielectric comprises bismuth, iron, barium, titanium, and oxygen.

Example 4 includes the subject matter of Example 1, wherein the dielectric comprises barium, zirconium, titanium, and oxygen.

Example 5 includes the subject matter of Example 1, wherein the dielectric comprises barium, niobium, titanium, and oxygen.

Example 6 includes the subject matter of any one of Examples 1-5, wherein the transistor device is a FinFET, a gate-all-around transistor, or a stacked gate-all-around transistor.

Example 7 includes the subject matter of any one of Examples 1-6, wherein a threshold voltage of the transistor device is less than 0.5V.

Example 8 is an integrated circuit device comprising the transistor device of any one of Examples 1-7.

Example 9 is a system comprising the integrated circuit device of Example 8 and one or more memory devices.

Example 10 is an integrated circuit device comprising: a transistor, the transistor comprising a gate dielectric, wherein the gate dielectric is ferroelectric and comprises a relaxor ferroelectric material.

Example 11 includes the subject matter of Example 10, wherein the relaxor ferroelectric material comprises barium, titanium, oxygen, and one or more of calcium, zirconium, bismuth, iron, and niobium.

Example 11.1 includes the subject matter of Example 11, wherein the dielectric comprises barium, calcium, titanium, zirconium, and oxygen.

Example 11.2 includes the subject matter of Example 11, wherein the dielectric comprises bismuth, iron, barium, titanium, and oxygen.

Example 11.3 includes the subject matter of Example 11, wherein the dielectric comprises barium, zirconium, titanium, and oxygen.

Example 11.4 includes the subject matter of Example 11, wherein the dielectric comprises barium, niobium, titanium, and oxygen.

Example 12 includes the subject matter of Example 10, 11, or any one of 11.1-11.4, wherein the transistor is a FinFET, a gate-all-around transistor, or a stacked gate-all-around transistor.

Example 13 includes the subject matter of any one of Examples 10-12, wherein a threshold voltage of the transistor device is less than 0.5V.

Example 14 is a processor comprising the integrated circuit device of any one of Example 10-12.

Example 15 is a system comprising the processor of Example 14 and one or more memory devices.

Example 16 is an integrated circuit device comprising: a transistor comprising: a channel region; a gate electrode; and a dielectric between the gate electrode and the channel region, wherein the dielectric comprises a relaxor ferroelectric material; wherein a threshold voltage of the transistor is less than 0.5 volts.

Example 17 includes the subject matter of Example 16, wherein the relaxor ferroelectric material comprises barium, titanium, oxygen, and one or more of calcium, zirconium, bismuth, iron, and niobium.

Example 17.1 includes the subject matter of Example 17, wherein the dielectric comprises barium, calcium, titanium, zirconium, and oxygen.

Example 17.2 includes the subject matter of Example 17, wherein the dielectric comprises bismuth, iron, barium, titanium, and oxygen.

Example 17.3 includes the subject matter of Example 17, wherein the dielectric comprises barium, zirconium, titanium, and oxygen.

Example 17.4 includes the subject matter of Example 17, wherein the dielectric comprises barium, niobium, titanium, and oxygen.

Example 18 includes the subject matter of any one of Examples 16, 17, and 17.1-17.4, wherein the transistor is one of a FinFET, a gate-all-around transistor, or a stacked gate-all-around transistor.

Example 19 is a processor comprising the integrated circuit device of any one of Examples 16, 17, and 17.1-17.4.

Example 20 is a system comprising the processor of Example 19 and one or more memory devices.

In the above description, various aspects of the illustrative implementations have been described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials, and configurations have been set forth to provide a thorough understanding of the illustrative implementations. However, it will be apparent to one skilled in the art that the present disclosure may be practiced without all of the specific details. In other instances, well-known features have been omitted or simplified in order not to obscure the illustrative implementations.

Further, concepts described herein are illustrated by way of example and not by way of limitation in the accompanying figures. It will be understood that in the examples shown and described further below, the figures may not be drawn to scale and may not include all possible layers and/or circuit components. In addition, it will be understood that although certain figures illustrate transistor designs with source/drain regions, electrodes, etc. having orthogonal (e.g., perpendicular) boundaries, embodiments herein may implement such boundaries in a substantially orthogonal manner (e.g., within +/−5 or 10 degrees of orthogonality) due to fabrication methods used to create such devices or for other reasons. Where considered appropriate, reference labels may have been repeated between certain Figures to indicate corresponding or analogous elements.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C). For the purposes of the present disclosure, the phrase “A and at least one of B and C” means (A and B), (A and C), or (A and B and C).

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

The above description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact. The phrase “communicatively coupled” may refer to the ability of a component to send a signal to or receive a signal from another component. The signal can be any type of signal, such as an input signal, an output signal, or a power signal. A component can send or receive a signal to another component to which it is communicatively coupled via a wired or wireless communication medium (e.g., conductive traces, conductive contacts, air). Examples of components that are communicatively coupled include integrated circuit dies located in the same package that communicate via an embedded bridge in a package substrate, and an integrated circuit component attached to a printed circuit board that send signals to or receives signals from other integrated circuit components or electronic devices attached to the printed circuit board.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

In various embodiments, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

In various embodiments, the term “adjacent” refers to layers or components that are in physical contact with each other. That is, there is no layer or component between the stated adjacent layers or components. For example, a layer X that is adjacent to a layer Y refers to a layer that is in physical contact with layer Y.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

1. A transistor device comprising:
a source region;
a drain region;
a channel region between the source region and the drain region;
a gate electrode; and
a dielectric between the gate electrode and the channel region, wherein the dielectric is ferroelectric and the dielectric comprises barium, titanium, oxygen, and one or more of calcium, zirconium, bismuth, iron, and niobium.

2. The transistor device of claim 1, wherein the dielectric comprises barium, calcium, titanium, zirconium, and oxygen.

3. The transistor device of claim 1, wherein the dielectric comprises bismuth, iron, barium, titanium, and oxygen.

4. The transistor device of claim 1, wherein the dielectric comprises barium, zirconium, titanium, and oxygen.

5. The transistor device of claim 1, wherein the dielectric comprises barium, niobium, titanium, and oxygen.

6. The transistor device of claim 1, wherein the transistor device is a FinFET, a gate-all-around transistor, or a stacked gate-all-around transistor.

7. The transistor device of claim 1, wherein a threshold voltage of the transistor device is less than 0.5V.

8. An integrated circuit device comprising the transistor device of claim 1.

9. A system comprising the integrated circuit device of claim 8 and one or more memory devices.

10. An integrated circuit device comprising:
a transistor, the transistor comprising a gate dielectric, wherein the gate dielectric is ferroelectric and comprises a relaxor ferroelectric material.

11. The integrated circuit device of claim 10, wherein the relaxor ferroelectric material comprises barium, titanium, oxygen, and one or more of calcium, zirconium, bismuth, iron, and niobium.

12. The integrated circuit device of claim 10, wherein the transistor is a FinFET, a gate-all-around transistor, or a stacked gate-all-around transistor.

13. The integrated circuit device of claim 10, wherein a threshold voltage of the transistor is less than 0.5V.

14. A processor comprising the integrated circuit device of claim 10.

15. A system comprising the processor of claim 14 and one or more memory devices.

16. An integrated circuit device comprising:
a transistor comprising:
a channel region;
a gate electrode; and
a dielectric between the gate electrode and the channel region, wherein the dielectric comprises a relaxor ferroelectric material;
wherein a threshold voltage of the transistor is less than 0.5 volts.

17. The integrated circuit device of claim 16, wherein the relaxor ferroelectric material comprises barium, titanium, oxygen, and one or more of calcium, zirconium, bismuth, iron, and niobium.

18. The integrated circuit device of claim 16, wherein the transistor is one of a FinFET, a gate-all-around transistor, or a stacked gate-all-around transistor.

19. A processor comprising the integrated circuit device of claim 16.

20. A system comprising the processor of claim 19 and one or more memory devices.
